(19) United States
(12) Patent Application Publication
(10) Pub. No.: US 2026/0089992 A1
(43) Pub. Date: Mar. 26, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Koji TANAKA, Tokyo (JP); Kazuya KONISHI, Tokyo (JP); Takashi FUJIMOTO, Tokyo (JP); Reona FURUKAWA, Tokyo (JP)

(73) Assignee: Mitsubishi Electric Corporation, Tokyo (JP)

(21) Appl. No.: 19/270,409

(22) Filed: Jul. 15, 2025

(30) Foreign Application Priority Data
Sep. 26, 2024 (JP) 2024-167079

(51) Int. Cl. H10D 12/00; H10D 12/01; H10D 62/10; H10D 64/27

(52) U.S. Cl. CPC H10D 12/481; H10D 12/038; H10D 62/102; H10D 62/124; H10D 64/516; H10D 64/518

(57) ABSTRACT

A semiconductor device includes a trench that penetrates a source layer and a base layer and reaches a drift layer, a first gate electrode that is disposed in a lower portion of the trench and has a side surface and a bottom surface on which a first gate insulating film is formed, and a second gate electrode that is disposed in an upper portion of the trench and has a side surface on which a second gate insulating film is formed. A thickness of a portion of the second gate insulating film in contact with the source layer is larger than a thickness of a portion of the second gate insulating film in contact with the base layer, and the portion of the second gate insulating film in contact with the source layer protrudes inward of the trench and does not protrude outward of the trench.

### BACKGROUND

### Technical Field

The present disclosure relates to a semiconductor device including a gate electrode embedded in a trench.

### Description of the Background Art

For example, Japanese Patent Application Laid-Open No. 2006-157016 discloses a semiconductor device having a structure in which a gate electrode divided into upper and lower portions is provided in a trench provided in a semiconductor substrate, and a gate insulating film around an upper gate electrode becomes thick near an upper end of the upper gate electrode.

In the semiconductor device of Japanese Patent Application Laid-Open No. 2006-157016, the gate insulating film around the upper gate electrode is thick so as to spread both inward (toward the gate electrode) and outward (toward the source layer) of the trench near the upper end of the upper gate electrode. When the gate insulating film is thick near the upper end of the upper gate electrode, Cgc/Cge, which is a ratio of a gate-emitter capacitance (Cge) and a gate-collector capacitance (Cgc), can be increased, and a turn-on loss (Eon) can be reduced. Since the area of the upper gate electrode in a sectional view is reduced, an effect that a gate charge amount (Qg), which is a charge amount required for charging and discharging the gate, can be reduced is also obtained.

However, since the gate electrode spreads not only inward (toward the gate electrode) of the trench but also toward both outward (toward the source layer) near the upper end portion of the upper gate electrode, there is a concern that a hole discharge efficiency at the time of turning off the semiconductor device deteriorates and the breakdown resistance at the time of turning off the semiconductor device decreases.

### SUMMARY

An object of the present disclosure is to increase a Cgc/Cge ratio and reduce Qg while preventing a decrease in breakdown resistance in a semiconductor device including a gate electrode divided into upper and lower portions in a trench.

A semiconductor device of the present disclosure includes a semiconductor substrate, a drift layer of a first conductivity type formed in the semiconductor substrate, a base layer of a second conductivity type formed in a surface portion of the semiconductor substrate, a source layer of the first conductivity type selectively formed in a surface portion of the base layer, and a trench formed in the semiconductor substrate so as to penetrate the source layer and the base layer and reach the drift layer. In the trench, there are provided an intermediate insulating film that divides the inside of the trench into upper and lower portions, a first gate electrode disposed in the trench below the intermediate insulating film and having a side surface and a bottom surface on which a first gate insulating film is formed, and a second gate electrode disposed in the trench on the intermediate insulating film and having a side surface on which a second gate insulating film is formed. An emitter electrode connected to the source layer is formed on the semiconductor substrate. The thickness of the portion of the second gate insulating film in contact with the source layer is larger than the thickness of the portion of the second gate insulating film in contact with the base layer. The portion of the second gate insulating film in contact with the source layer protrudes inward of the trench, but does not protrude outward of the trench.

The present disclosure can increase the Cgc/Cge ratio and reduce Qg while preventing a decrease in breakdown resistance in the semiconductor device including the gate electrode divided into upper and lower portions in the trench.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a sectional view illustrating a configuration of a semiconductor device according to a first preferred embodiment;

FIG. 2 is a sectional view illustrating a configuration of a semiconductor device according to a second preferred embodiment;

FIG. 3 is a sectional view illustrating a configuration of a semiconductor device according to a third preferred embodiment;

FIG. 4 is a sectional view illustrating a configuration of a semiconductor device according to a fourth preferred embodiment;

FIG. 5 is a sectional view illustrating a configuration of a semiconductor device according to a fifth preferred embodiment;

FIG. 6 is a sectional view illustrating a configuration of a semiconductor device according to a sixth preferred embodiment; and

FIGS. 7 to 22 are explanatory diagrams illustrating a method of manufacturing a semiconductor device according to a seventh preferred embodiment.

### DESCRIPTION OF THE PREFERRED EMBODIMENTS

Preferred embodiments of the technology of the present disclosure will be described. In the following description, N-type and P-type indicate the conductivity type of a semiconductor, and in each preferred embodiment, a first conductivity type is described as N-type and a second conductivity type is described as P-type, but conversely, the first conductivity type may be P-type and the second conductivity type may be N-type. The level of an impurity concentration of each region is defined by a peak concentration. That is, a region having a high (or low) impurity concentration means a region having a high (or low) impurity peak concentration.

In the drawings shown below, the same or corresponding elements are denoted by the same reference numerals. Therefore, description of elements denoted by the same reference numerals as those described above will be appropriately omitted.

### First Preferred Embodiment

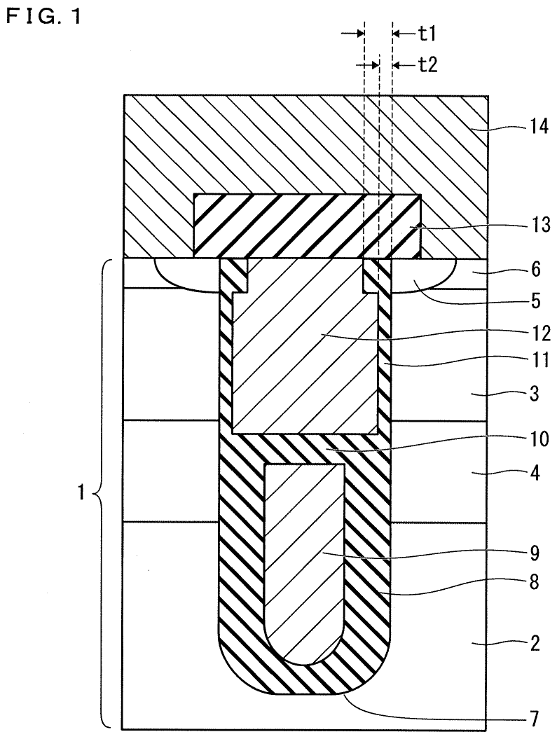

FIG. 1 is a sectional view illustrating a configuration of a semiconductor device according to a first preferred embodiment. Here, a semiconductor element included in the semiconductor device will be described as an insulated gate bipolar transistor (IGBT). However, the semiconductor element only needs to be a trench-type insulated gate semiconductor element, and may be, for example, an element other than an IGBT, such as a metal oxide semiconductor field effect transistor (MOSFET).

As illustrated in FIG. 1, the semiconductor device according to the first preferred embodiment is formed by using a semiconductor substrate 1 on which an N-type drift layer 2 is formed. A P-type base layer 3 is formed in a surface portion on an upper surface side of the semiconductor substrate 1. An N-type carrier stored layer 4 having a higher impurity concentration than the drift layer 2 is formed between the drift layer 2 and the base layer 3. However, the carrier stored layer 4 may be omitted (that is, the drift layer 2 may be formed up to the portion of the carrier stored layer 4 in FIG. 1). By providing the carrier stored layer 4, the energization loss of the IGBT can be reduced.

In a surface portion of the base layer 3, an N-type source layer 5 and a P-type contact layer 6 having a higher impurity concentration than the base layer 3 are selectively formed. The contact layer 6 may be omitted (that is, the base layer 3 may be formed up to the portion of the contact layer 6 in FIG. 1). By providing the contact layer 6, the connection resistance between an emitter electrode 14 described later and the base layer 3 can be reduced.

On the upper surface of the semiconductor substrate 1, a trench 7 that penetrates the source layer 5, the base layer 3, and the carrier stored layer 4 and reaches the drift layer 2 below the carrier stored layer 4 is formed. The trench 7 is divided into upper and lower portions by an intermediate insulating film 10, a first gate electrode 9 having a side surface and a bottom surface on which a first gate insulating film 8 is formed is disposed below the intermediate insulating film 10, and a second gate electrode 12 having a side surface on which a second gate insulating film 11 is formed is disposed on the intermediate insulating film 10.

On the semiconductor substrate 1, an interlayer insulating film 13 is formed so as to cover the second gate electrode 12, and the emitter electrode 14 is formed on the interlayer insulating film 13. A contact hole reaching the source layer 5 and the contact layer 6 is formed in the interlayer insulating film 13, and the emitter electrode 14 is connected to the source layer 5 and the contact layer 6 through the contact hole.

Here, in the semiconductor device according to the first preferred embodiment, in the second gate insulating film 11 provided on a side surface of the second gate electrode 12, a thickness t1 of the portion in contact with the source layer 5 is larger than a thickness t2 of the portion in contact with the base layer 3. However, the thickness of the portion of the second gate insulating film 11 in contact with the source layer 5 spreads only inward of the trench 7 (toward the second gate electrode 12) and does not spread outward of the trench 7 (toward the source layer 5). That is, as illustrated in FIG. 1, in a sectional view, a portion of the second gate insulating film 11 in contact with the source layer 5 protrudes inward of the trench 7, but does not protrude outward of the trench 7.

In the semiconductor device according to the first preferred embodiment, since the thickness of the portion of the second gate insulating film 11 in contact with the source layer 5 is large, a gate-emitter capacitance (Cge) is reduced. Therefore, Cgc/Cge, which is a ratio between Cge and a gate-collector capacitance (Cgc), increases, and a turn-on loss (Eon) of the semiconductor device can be reduced.

In the semiconductor device according to the first preferred embodiment, the second gate electrode 12 is reduced in size by the amount of protrusion of the portion of the second gate insulating film 11 in contact with the source layer 5 inward of the trench 7 (toward the second gate electrode 12). Since a gate charge amount (Qg), which is a charge amount necessary for charging and discharging the gate, is proportional to a volume or an area in a sectional view of the second gate electrode 12, the effect that Qg becomes small and the semiconductor device can be turned on with a small charge amount can also be obtained. Here, since the portion of the second gate insulating film 11 in contact with the source layer 5 does not protrude outward of the trench 7 (toward the source layer 5), a hole discharge efficiency at the time of turn-off of the semiconductor device is not deteriorated, and a breakdown resistance at the time of turn-off is not reduced.

### Second Preferred Embodiment

In FIG. 1, the thickness t1 of the portion of the second gate insulating film 11 in contact with the source layer 5 is uniform, but the shape of the portion is not limited to this shape. That is, the portion of the second gate insulating film 11 in contact with the source layer 5 may have any shape as long as the thickness t1 is thicker than the thickness t2 of the portion in contact with the base layer 3 and does not protrude outward of the trench 7.

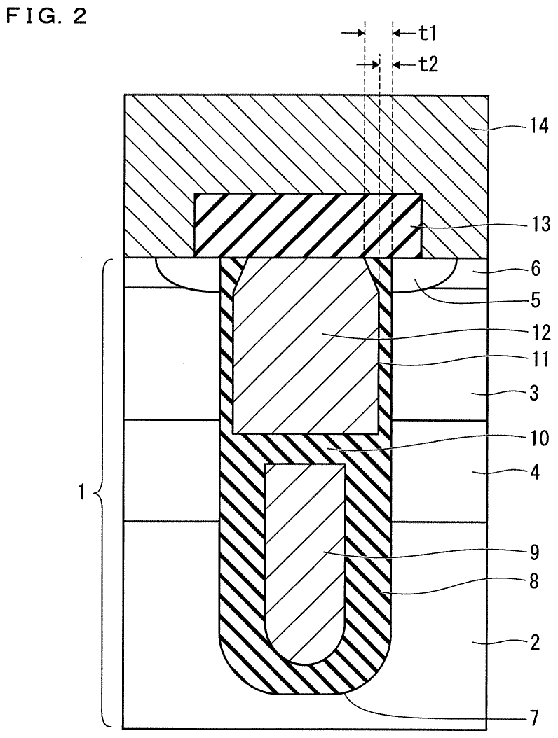

FIG. 2 is a sectional view illustrating a configuration of a semiconductor device according to a second preferred embodiment. As illustrated in FIG. 2, in the semiconductor device according to the second preferred embodiment, a portion of the second gate insulating film 11 in contact with the source layer 5 has a shape gradually expanding upward. That is, the thickness of the portion of the second gate insulating film 11 in contact with the source layer 5 increases toward an upper end of the trench 7. However, the portion of the second gate insulating film 11 in contact with the source layer 5 does not extend outward of the trench 7.

In the semiconductor device according to the second preferred embodiment, the same effects as those of the first preferred embodiment can be obtained.

### Third Preferred Embodiment

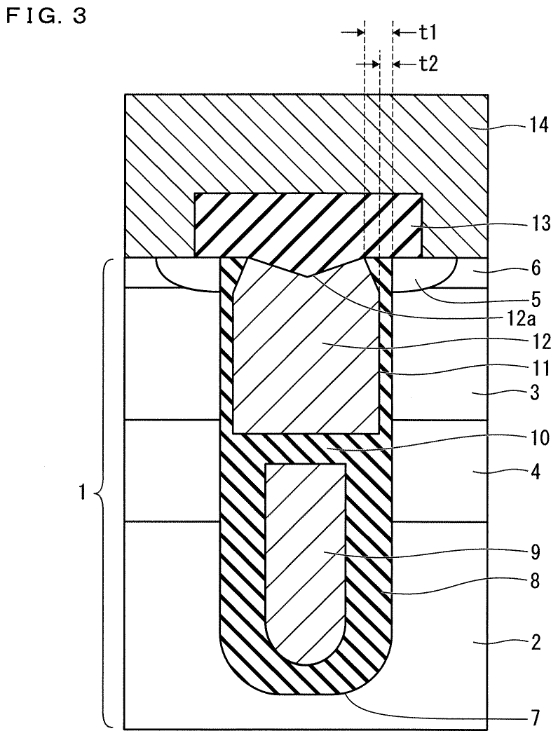

FIG. 3 is a sectional view illustrating a configuration of a semiconductor device according to a third preferred embodiment. As illustrated in FIG. 3, in the semiconductor device according to the third preferred embodiment, a recess 12a is provided on an upper surface of the second gate electrode 12. A part of the interlayer insulating film 13 is embedded in the recess 12a.

In the semiconductor device according to the third preferred embodiment, in addition to the portion of the second gate insulating film 11 in contact with the source layer 5 protruding inward of the trench 7 (toward the second gate electrode 12), a volume or an area in a sectional view of the second gate electrode 12 is further reduced by the presence of the recess 12a on the upper surface of the second gate electrode 12. Therefore, an effect of further reducing the Qg of the semiconductor device can be obtained in the third preferred embodiment.

### Fourth Preferred Embodiment

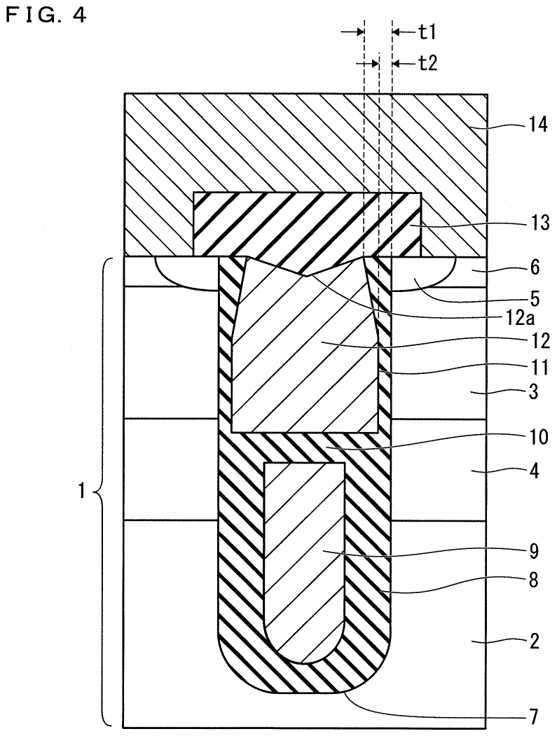

FIG. 4 is a sectional view illustrating a configuration of a semiconductor device according to a fourth preferred embodiment. As illustrated in FIG. 4, in the semiconductor device according to the fourth preferred embodiment, a thick portion of the second gate insulating film 11 reaches a position deeper than the source layer 5. In the second gate insulating film 11, not only the portion of the second gate insulating film 11 in contact with the source layer 5 but also an upper portion of the portion of the second gate insulating film 11 in contact with the base layer 3 (near a boundary between the base layer 3 and the source layer 5) protrudes inward of the trench 7 and becomes thick. That is, the second gate insulating film 11 is thick so as to protrude inward of the trench 7 in the region from the upper portion of the portion in contact with the base layer 3 to the portion in contact with the source layer 5.

In the example in FIG. 4, in the region from the upper portion of the portion of the second gate insulating film 11 in contact with the base layer 3 to the portion in contact with the source layer 5, the thickness of the second gate insulating film 11 increases toward the upper end of the trench 7. However, the shape of the second gate insulating film 11 is not limited to this shape, and for example, the thickness of the thick portion of the second gate insulating film 11 may be uniform.

In the semiconductor device of the fourth preferred embodiment, not only the thickness of the portion of the second gate insulating film 11 in contact with the source layer 5 but also the thickness of the upper portion of the portion of the second gate insulating film 11 in contact with the base layer 3 (near the boundary between the base layer 3 and the source layer 5) is large. Therefore, Cgc/Cge can be further increased and Qg can be further decreased.

### Fifth Preferred Embodiment

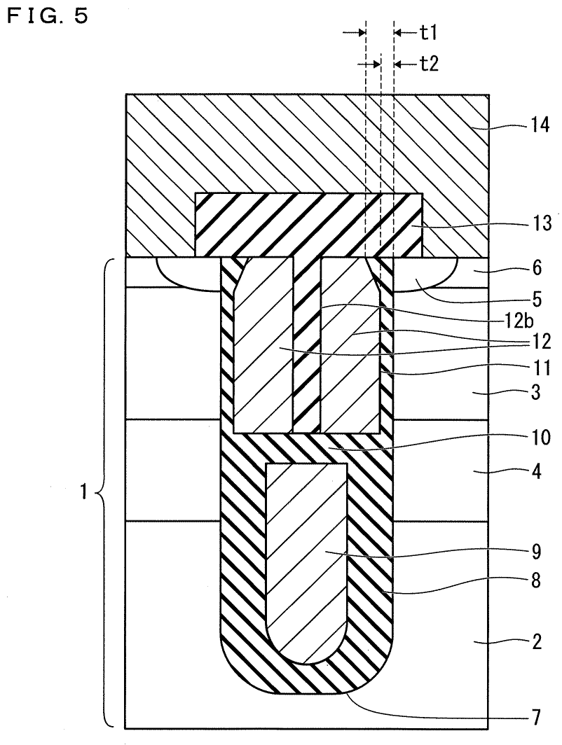

FIG. 5 is a sectional view illustrating a configuration of a semiconductor device according to a fifth preferred embodiment. As illustrated in FIG. 5, in the semiconductor device according to the fifth preferred embodiment, an opening 12b extending from an upper surface to a bottom surface of the second gate electrode 12 is formed in the second gate electrode 12. In FIG. 5, the opening 12b reaches the intermediate insulating film 10 at a bottom of the second gate electrode 12, and divides the second gate electrode 12 into two. A part of the interlayer insulating film 13 is embedded in the opening 12b.

Since the opening 12b of the second gate electrode 12 is formed deeper than the opening 12b described in the third preferred embodiment, a volume or an area in a sectional view of second gate electrode 12 can be further reduced. Therefore, an effect of further reducing the Qg of the semiconductor device can be obtained in the semiconductor device according to the fifth preferred embodiment.

Note that the opening 12b is not required to divide the second gate electrode 12. That is, the second gate electrodes 12 on the left and right of the opening 12b in FIG. 5 may be connected to each other. For example, the opening 12b may have an island shape in plan view, or the opening 12b is not required to reach the intermediate insulating film 10.

### Sixth Preferred Embodiment

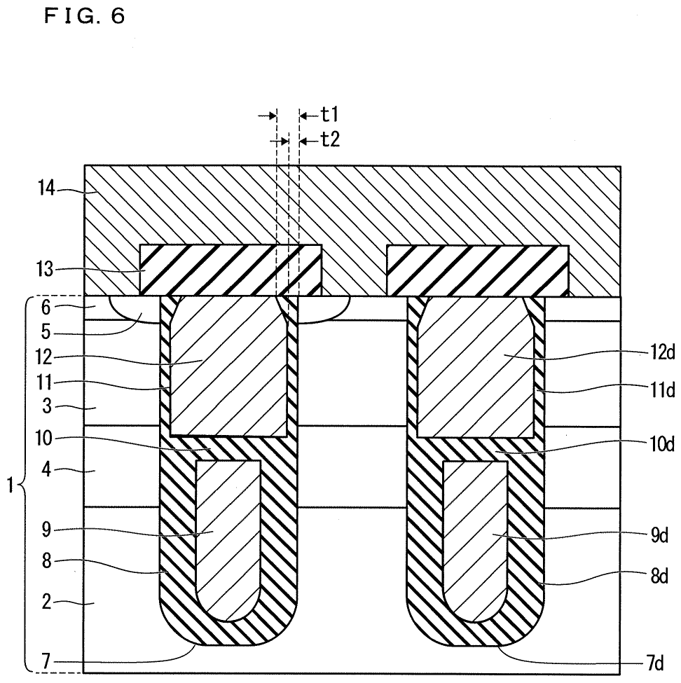

FIG. 6 is a sectional view illustrating a configuration of a semiconductor device according to a sixth preferred embodiment. As illustrated in FIG. 6, the semiconductor device according to the sixth preferred embodiment is obtained by adding a dummy trench 7d to the configuration of the second preferred embodiment (FIG. 2). In other words, the semiconductor device according to the sixth preferred embodiment is obtained by replacing a part of the trench 7 with the dummy trench 7d in the semiconductor device according to the second preferred embodiment. For convenience of description, the trench 7 is referred to as an “active trench 7”in the present preferred embodiment.

The dummy trench 7d is not in contact with the source layer 5, penetrates the contact layer 6, the base layer 3, and the carrier stored layer 4, and reaches the drift layer 2 below the carrier stored layer 4. The structure in the dummy trench 7d is similar to the structure in the active trench 7. The dummy trench 7d is divided into upper and lower portions by a dummy intermediate insulating film 10d, a first dummy gate electrode 9d having a first dummy gate insulating film 8d on the side surface is formed below the dummy intermediate insulating film 10d, and a second dummy gate electrode 12d having a side surface on which a second dummy gate insulating film 11d is formed on the dummy intermediate insulating film 10d. However, a gate potential is supplied to the first dummy gate electrode 9d similarly to the first gate electrode 9, but an emitter potential is supplied to the second dummy gate electrode 12d. That is, the second dummy gate electrode 12d is electrically connected to the emitter electrode 14.

The second dummy gate insulating film 11d in the dummy trench 7d has a similar shape to the second gate insulating film 11 in the active trench 7. That is, an upper portion (a portion in contact with the contact layer 6 in FIG. 6) of the second dummy gate insulating film 11d is thicker than other portions. However, the thickness of the upper portion of the second dummy gate insulating film 11d spreads only inward of the dummy trench 7d (toward the second dummy gate electrode 12d), and does not spread outward of the dummy trench 7d (toward the source layer 5). That is, in a sectional view, the upper portion of the second dummy gate insulating film 11d protrudes inward of the dummy trench 7d, but does not protrude outward of the dummy trench 7d.

If an interval between the active trenches 7 is narrowed, a withstand voltage of the semiconductor device can be improved, but a density of the second gate electrode 12 is increased, and an increase in the gate charge amount (Qg) is concerned. As in the present preferred embodiment, the increase in Qg can be suppressed by replacing a part of the active trench 7 with the dummy trench 7d.

Since the upper portion of the second dummy gate insulating film 11d is thick, the capacitance between the second gate electrode 12 in the active trench 7 to which the gate potential is supplied and the second dummy gate electrode 12d of the dummy trench 7d to which the emitter potential is supplied is reduced. Therefore, Cgc is reduced, and an effect of increasing Cgc/Cge is obtained.

### Seventh Preferred Embodiment

In a seventh preferred embodiment, a method of manufacturing a semiconductor device of the present disclosure will be described. Here, a method of manufacturing the semiconductor device (FIG. 2) according to the second preferred embodiment will be representatively described.

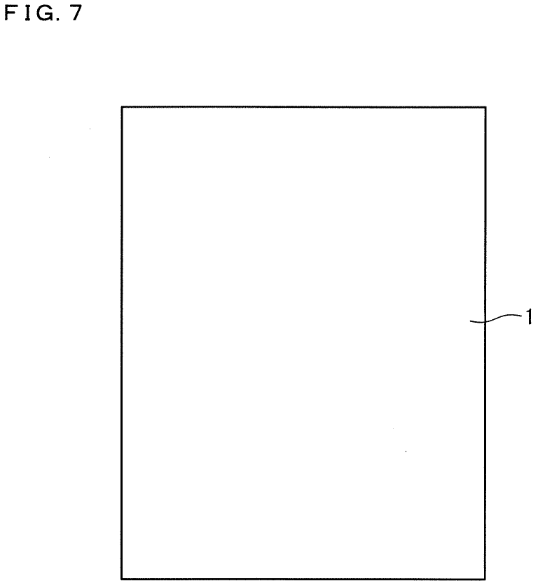

First, as illustrated in FIG. 7, an N-type semiconductor substrate 1 is prepared. Here, the semiconductor substrate 1 includes silicon (Si). The semiconductor substrate 1 may include silicon carbide (SiC) known as a wide band gap semiconductor.

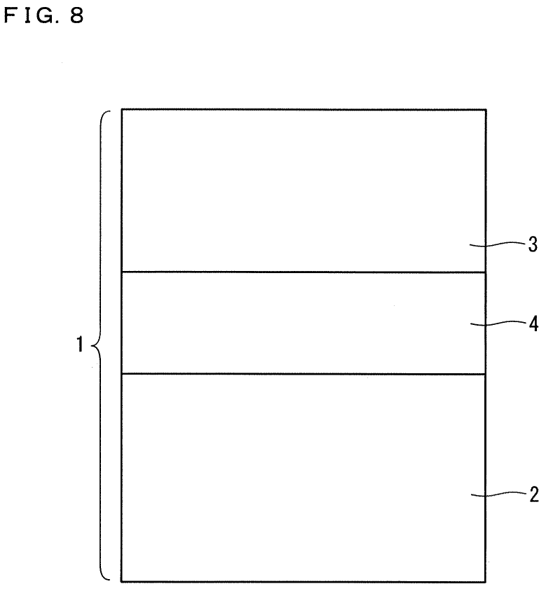

Next, as illustrated in FIG. 8, the base layer 3 and the carrier stored layer 4 are formed in the surface portion of the semiconductor substrate 1 by selective ion implantation using a photoengraving technique. At this time, an N-type region where the base layer 3 and the carrier stored layer 4 are not formed is left to be the drift layer 2.

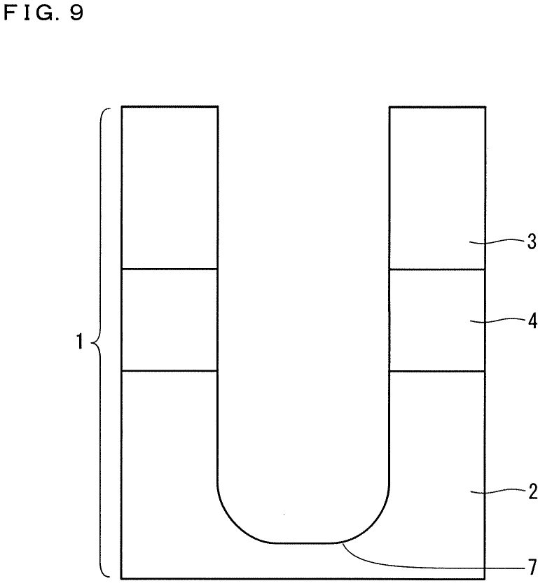

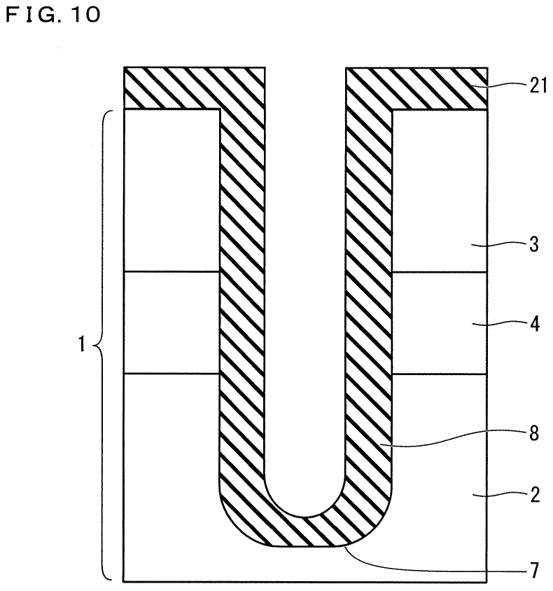

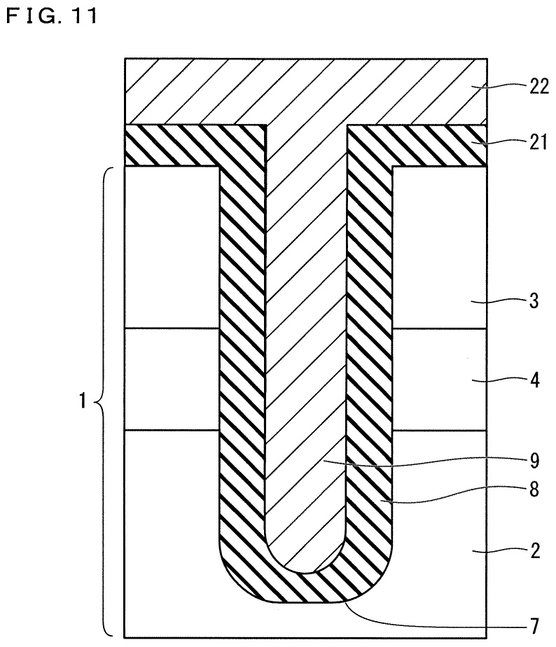

Subsequently, trenches 7 are formed in the semiconductor substrate 1 by selective etching using the photoengraving technique as illustrated in FIG. 9. Thereafter, as illustrated in FIG. 10, a first insulating film 21 which is a material of the first gate insulating film 8 is formed on the upper surface of the semiconductor substrate 1 including an inner surface of the trench 7. The first insulating film 21 is, for example, a silicon oxide film. As illustrated in FIG. 11, a first conductive film 22 which is a material of the first gate electrode 9 is formed on the first insulating film 21 to embed the first conductive film 22 in the trench 7. The first conductive film 22 is, for example, polysilicon.

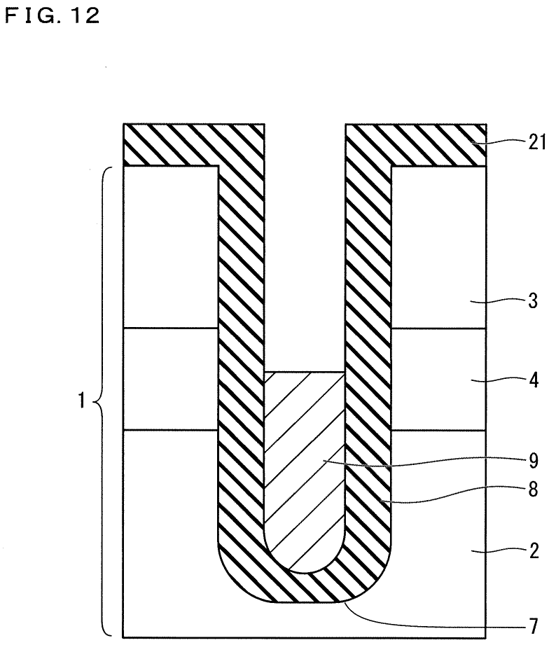

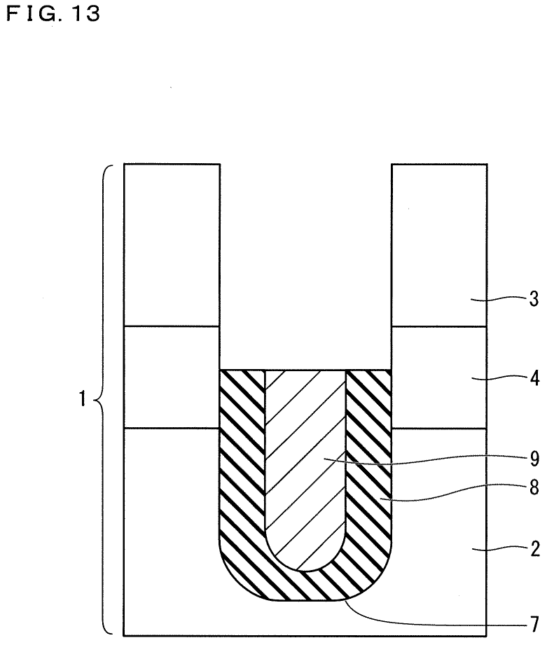

Then, by etching the first conductive film 22, the first conductive film 22 on the upper surface of the semiconductor substrate 1 and the upper portion in the trench 7 is removed as illustrated in FIG. 12. At this time, the first conductive film 22 left at a lower portion in the trench 7 becomes the first gate electrode 9. By etching the first insulating film 21, the first insulating film 21 on the upper surface of the semiconductor substrate 1 and the upper portion in the trench 7 is removed as illustrated in FIG. 13. At this time, the first insulating film 21 left at the lower portion in the trench 7 becomes the first gate insulating film 8.

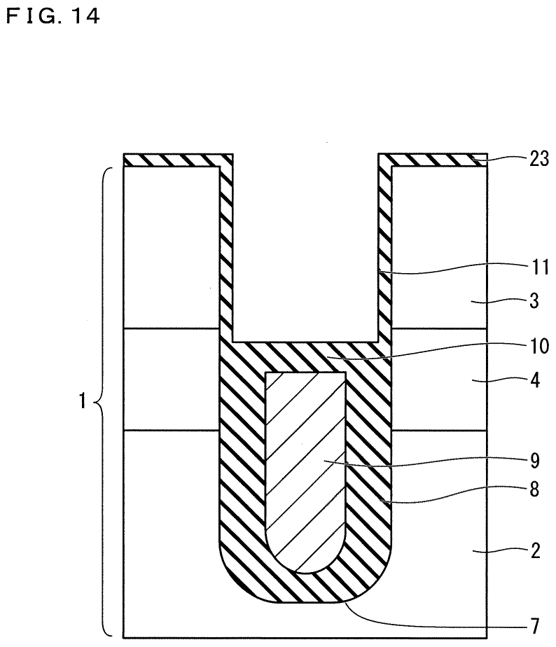

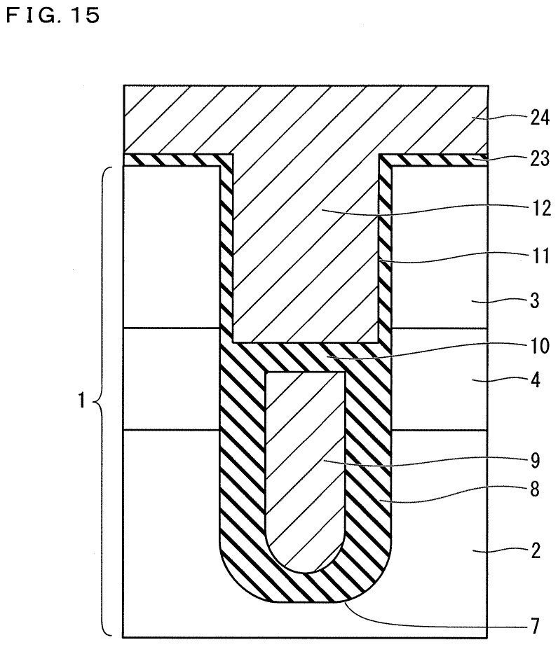

Subsequently, as illustrated in FIG. 14, a second insulating film 23 which is a material of the second gate insulating film 11 is formed on the upper surface of the semiconductor substrate 1 including the inner surface of the trench 7. The second insulating film 23 is, for example, a silicon oxide film. At this time, a portion of the second insulating film 23 formed so as to cover the upper surface of the first gate electrode 9 becomes the intermediate insulating film 10. As illustrated in FIG. 15, the second conductive film 24 made of the material of the second gate electrode 12 is formed on the second insulating film 23 to embed the second conductive film 24 in the trench 7. The second conductive film 24 is, for example, polysilicon.

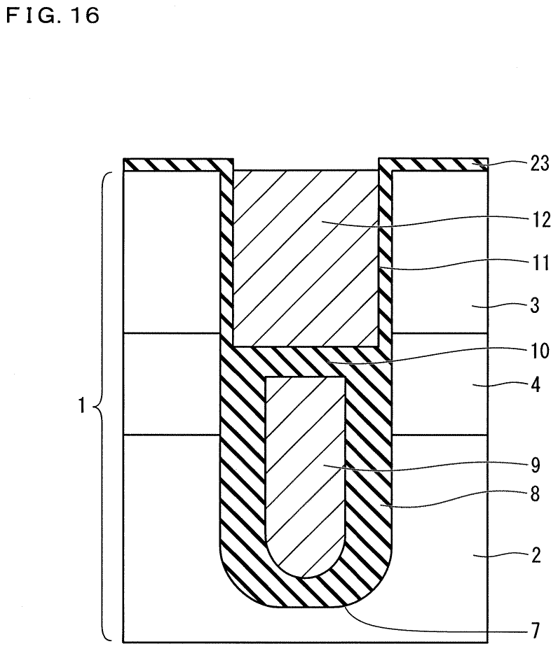

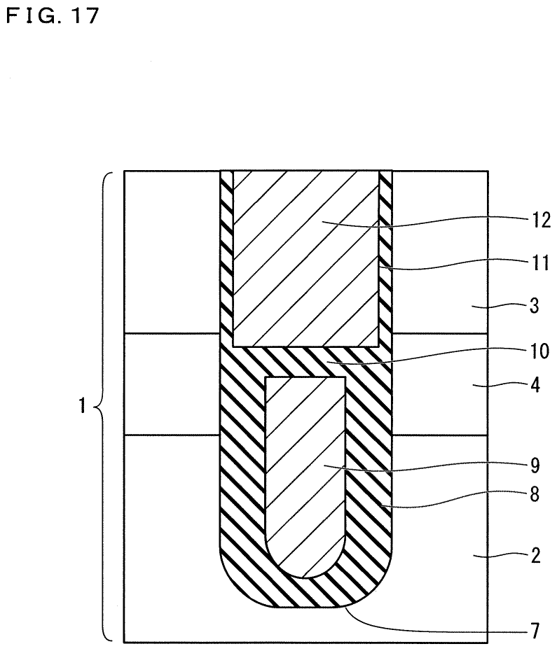

Then, as illustrated in FIG. 16, the second conductive film 24 on the upper surface of the semiconductor substrate 1 is removed by etching the second conductive film 24. At this time, the second conductive film 24 left in the trench 7 becomes the second gate electrode 12. The second insulating film 23 on the upper surface of the semiconductor substrate 1 is removed as illustrated in FIG. 17 by etching the second insulating film 23. At this time, the second insulating film 23 left in the trench 7 becomes the second gate insulating film 11.

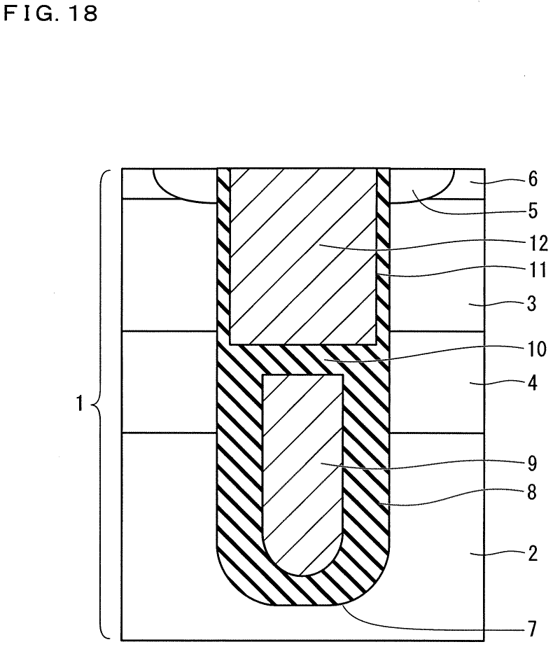

Subsequently, as illustrated in FIG. 18, the source layer 5 and the contact layer 6 are formed in the surface portion of the base layer 3 by selective etching using the photoengraving technique.

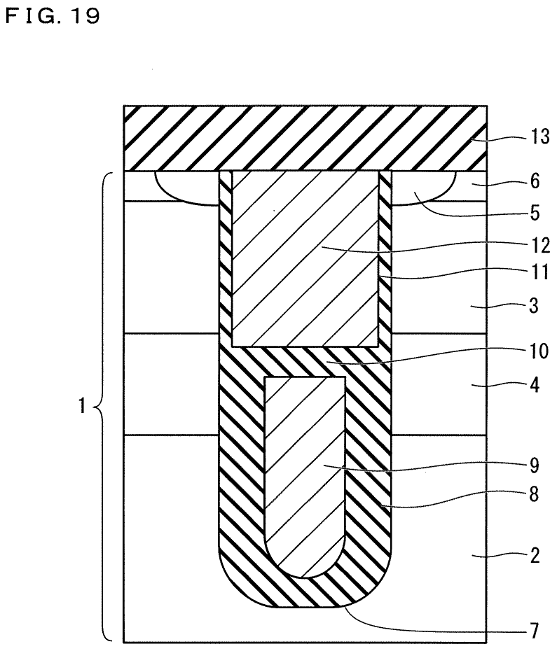

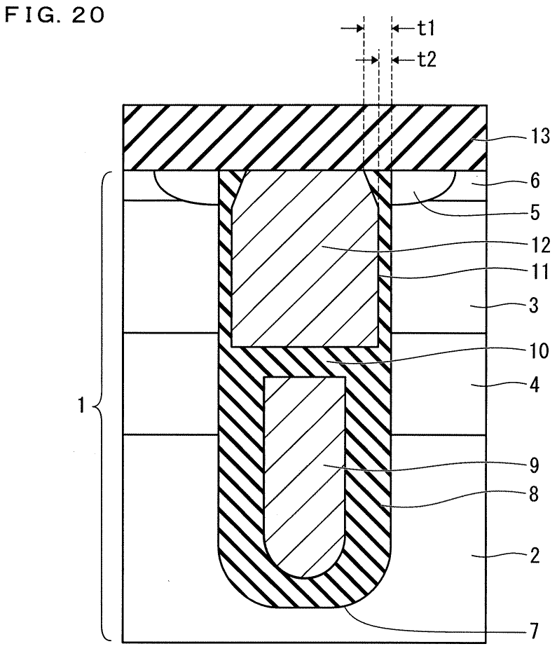

Thereafter, the interlayer insulating film 13 including a silicon oxide film is formed on the semiconductor substrate 1 by chemical vapor deposition (CVD) as illustrated in FIG. 19. Then, the interlayer insulating film 13 is annealed in an oxygen atmosphere. As a result, oxygen diffuses into the oxide film constituting the interlayer insulating film 13, oxidation of the second gate electrode 12 and the semiconductor substrate 1 proceeds near the upper portion of the second gate insulating film 11, and the thickness of the second gate insulating film 11 increases. However, an oxidation rate of the semiconductor substrate 1 including silicon is extremely slower than an oxidation rate of the second gate electrode 12 including polysilicon, and the oxidation of the semiconductor substrate 1 is negligible. Therefore, as illustrated in FIG. 20, the second gate insulating film 11 spreads only inward of the trench 7 (toward the second gate electrode 12), and does not spread outward of the trench 7 (toward the contact layer 6).

As a result, in a sectional view, a portion of the second gate insulating film 11 in contact with the source layer 5 protrudes inward of the trench 7, but does not protrude outward of the trench 7. The thickness t1 of the portion of the second gate insulating film 11 in contact with the source layer 5 is larger than the thickness t2 of the portion of the second gate insulating film 11 in contact with the base layer 3. Since the oxidation of the second gate electrode 12 proceeds from the upper side in contact with the interlayer insulating film 13, the thickness of the portion of the second gate insulating film 11 in contact with the source layer 5 increases toward the upper end of the trench 7. Therefore, the shape of the second gate insulating film 11 is as in the second preferred embodiment (FIG. 2).

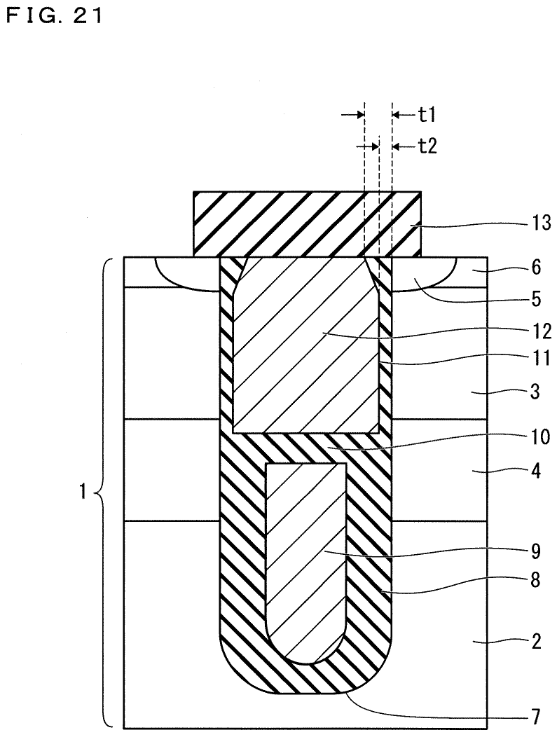

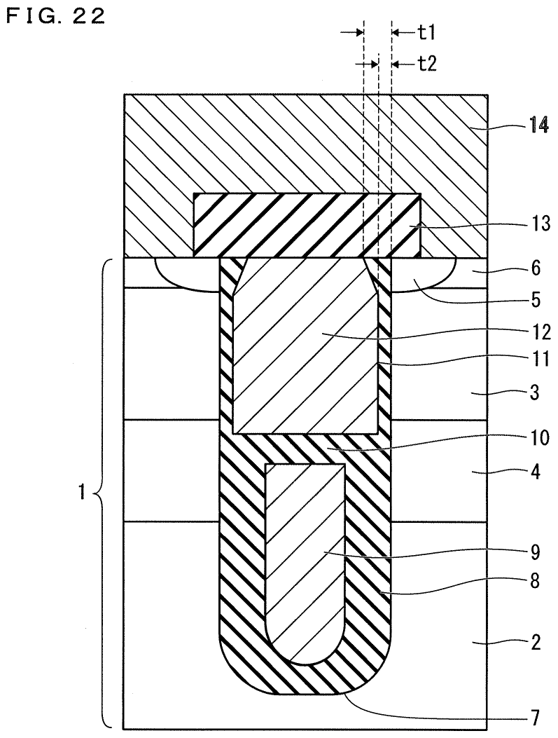

Thereafter, selective etching using the photoengraving technique is performed on the interlayer insulating film 13 to form a contact hole reaching the source layer 5 and the contact layer 6 in the interlayer insulating film 13 as illustrated in FIG. 21. Then, as illustrated in FIG. 22, the emitter electrode 14 including, for example, a metal material is formed on the interlayer insulating film 13. At this time, the emitter electrode 14 is connected to the source layer 5 and the contact layer 6 through the contact hole.

As described above, the semiconductor device (FIG. 2) according to the second preferred embodiment is formed.

When the recess 12a is provided on the upper surface of the second gate electrode 12 as in the third preferred embodiment (FIG. 3), the thickness of the deposited second conductive film 24 may be reduced in a step of forming the second conductive film 24 which is the material of the second gate electrode 12 (FIG. 15).

When the thick portion of the second gate insulating film 11 is extended to a position deeper than the contact layer 6 as in the fourth preferred embodiment (FIG. 4), annealing time is only required to be lengthened or an annealing temperature is only required to be increased in a step of performing annealing in an oxygen atmosphere (FIG. 20).

When the opening 12b is provided on the upper surface of the second gate electrode 12 as in the fifth preferred embodiment (FIG. 5), it is necessary to add a step of forming the opening 12b in the second gate electrode 12 by selective etching after a step of forming the second gate electrode 12 (FIG. 18).

Note that the preferred embodiments can be freely combined, and the preferred embodiments can be appropriately modified or omitted.

### APPENDIXES

Hereinafter, various modes of the present disclosure will be collectively described as appendixes.

### Appendix 1

A semiconductor device comprising:
a semiconductor substrate;
a drift layer of a first conductivity type formed on the semiconductor substrate;
a base layer of a second conductivity type formed in a surface portion of the semiconductor substrate;
a source layer of the first conductivity type selectively formed in a surface portion of the base layer;
a trench formed in the semiconductor substrate so as to penetrate the source layer and the base layer and reach the drift layer;
an intermediate insulating film that divides an inside of the trench into upper and lower portions;
a first gate electrode disposed in the trench below the intermediate insulating film and having a side surface and a bottom surface on which a first gate insulating film is formed;
a second gate electrode disposed in the trench on the intermediate insulating film and having a side surface on which a second gate insulating film is formed; and
an emitter electrode formed on the semiconductor substrate and connected to the source layer, wherein
a thickness of a portion of the second gate insulating film in contact with the source layer is larger than a thickness of a portion of the second gate insulating film in contact with the base layer, and
the portion of the second gate insulating film in contact with the source layer protrudes inward of the trench and does not protrude outward of the trench.

### Appendix 2

The semiconductor device according to Appendix 1, wherein
the thickness of the portion of the second gate insulating film in contact with the source layer increases toward an upper end of the trench.

### Appendix 3

The semiconductor device according to Appendix 1 or 2, wherein
the second gate insulating film protrudes inward of the trench in a region from an upper portion of the portion in contact with the base layer to the portion in contact with the source layer.

### Appendix 4

The semiconductor device according to any one of Appendixes 1 to 3, wherein
the second gate electrode includes a recess on an upper surface.

### Appendix 5

The semiconductor device according to any one of Appendixes 1 to 3, wherein
an opening extending from the upper surface to a bottom surface of the second gate electrode is formed in the second gate electrode.

### Appendix 6

The semiconductor device according to Appendix 5, wherein
the opening reaches a bottom of the second gate electrode.

### Appendix 7

The semiconductor device according to any one of Appendixes 1 to 6, further comprising:
a dummy trench not in contact with the source layer and formed in the semiconductor substrate so as to penetrate the base layer and reach the drift layer;
a dummy intermediate insulating film that divides an inside of the dummy trench into upper and lower portions;
a first dummy gate electrode disposed in the dummy trench below the dummy intermediate insulating film and having a side surface and a bottom surface on which a first dummy gate insulating film is formed; and
a second dummy gate electrode disposed in the dummy trench on the dummy intermediate insulating film and having a side surface on which a second dummy gate insulating film is formed, wherein
the second dummy gate electrode is electrically connected to the emitter electrode,
a thickness of a portion of the second dummy gate insulating film in contact with the source layer is larger than a thickness of a portion of the second dummy gate insulating film in contact with the base layer, and
the portion of the second dummy gate insulating film in contact with the source layer protrudes inward of the dummy trench and does not protrude outward of the dummy trench.

### Appendix 8

A method of manufacturing a semiconductor device, the method comprising steps of:
preparing a semiconductor substrate of a first conductivity type;
forming a base layer of a second conductivity type in a surface portion of the semiconductor substrate;
forming a trench that reaches below the base layer in the semiconductor substrate;
forming a first insulating film on an upper surface of the semiconductor substrate including an inner surface of the trench;
embedding a first conductive film in the trench by forming the first conductive film on the first insulating film;
forming a first gate insulating film made of the first insulating film and a first gate electrode made of the first conductive film in a lower portion in the trench by removing the first insulating film and the first conductive film on the upper surface of the semiconductor substrate and in an upper portion in the trench;
forming a second insulating film on the upper surface of the semiconductor substrate including the inner surface of the trench after forming the first gate insulating film and the first gate electrode;
embedding a second conductive film in the trench by forming the second conductive film on the second insulating film;
forming a second gate insulating film made of the second insulating film and a second gate electrode made of the second conductive film in the upper portion in the trench by removing the second insulating film and the second conductive film on the upper surface of the semiconductor substrate;
forming a source layer of the first conductivity type in a surface portion of the base layer;
forming an interlayer insulating film including an oxide film so as to cover the second gate insulating film and the second gate electrode; and
performing annealing in an oxygen atmosphere on the interlayer insulating film.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor substrate;
a drift layer of a first conductivity type formed on the semiconductor substrate;
a base layer of a second conductivity type formed in a surface portion of the semiconductor substrate;
a source layer of the first conductivity type selectively formed in a surface portion of the base layer;
a trench formed in the semiconductor substrate so as to penetrate the source layer and the base layer and reach the drift layer;
an intermediate insulating film that divides an inside of the trench into upper and lower portions;
a first gate electrode disposed in the trench below the intermediate insulating film and having a side surface and a bottom surface on which a first gate insulating film is formed;
a second gate electrode disposed in the trench on the intermediate insulating film and having a side surface on which a second gate insulating film is formed; and
an emitter electrode formed on the semiconductor substrate and connected to the source layer, wherein
a thickness of a portion of the second gate insulating film in contact with the source layer is larger than a thickness of a portion of the second gate insulating film in contact with the base layer, and
the portion of the second gate insulating film in contact with the source layer protrudes inward of the trench and does not protrude outward of the trench.

2. The semiconductor device according to claim 1, wherein
the thickness of the portion of the second gate insulating film in contact with the source layer increases toward an upper end of the trench.

3. The semiconductor device according to claim 1, wherein
the second gate insulating film protrudes inward of the trench in a region from an upper portion of the portion in contact with the base layer to the portion in contact with the source layer.

4. The semiconductor device according to claim 1, wherein the second gate electrode includes a recess on an upper surface.

5. The semiconductor device according to claim 1, wherein
an opening extending from the upper surface to a bottom surface of the second gate electrode is formed in the second gate electrode.

6. The semiconductor device according to claim 5, wherein the opening reaches a bottom of the second gate electrode.

7. The semiconductor device according to claim 1, further comprising:
a dummy trench not in contact with the source layer and formed in the semiconductor substrate so as to penetrate the base layer and reach the drift layer;
a dummy intermediate insulating film that divides an inside of the dummy trench into upper and lower portions;
a first dummy gate electrode disposed in the dummy trench below the dummy intermediate insulating film and having a side surface and a bottom surface on which a first dummy gate insulating film is formed; and
a second dummy gate electrode disposed in the dummy trench on the dummy intermediate insulating film and having a side surface on which a second dummy gate insulating film is formed, wherein
the second dummy gate electrode is electrically connected to the emitter electrode,
a thickness of a portion of the second dummy gate insulating film in contact with the source layer is larger than a thickness of a portion of the second dummy gate insulating film in contact with the base layer, and
the portion of the second dummy gate insulating film in contact with the source layer protrudes inward of the dummy trench and does not protrude outward of the dummy trench.

8. A method of manufacturing a semiconductor device, the method comprising steps of:
preparing a semiconductor substrate of a first conductivity type;
forming a base layer of a second conductivity type in a surface portion of the semiconductor substrate;
forming a trench that reaches below the base layer in the semiconductor substrate;
forming a first insulating film on an upper surface of the semiconductor substrate including an inner surface of the trench;
embedding a first conductive film in the trench by forming the first conductive film on the first insulating film;
forming a first gate insulating film made of the first insulating film and a first gate electrode made of the first conductive film in a lower portion in the trench by removing the first insulating film and the first conductive film on the upper surface of the semiconductor substrate and in an upper portion in the trench;
forming a second insulating film on the upper surface of the semiconductor substrate including the inner surface of the trench after forming the first gate insulating film and the first gate electrode;
embedding a second conductive film in the trench by forming the second conductive film on the second insulating film;
forming a second gate insulating film made of the second insulating film and a second gate electrode made of the second conductive film in the upper portion in the trench by removing the second insulating film and the second conductive film on the upper surface of the semiconductor substrate;
forming a source layer of the first conductivity type in a surface portion of the base layer;
forming an interlayer insulating film including an oxide film so as to cover the second gate insulating film and the second gate electrode; and
performing annealing in an oxygen atmosphere on the interlayer insulating film.
